(19) United States
(12) Patent Application Publication
(10) Pub. No.: US 2014/0230207 A1
(43) Pub. Date: Aug. 21, 2014

(54) LIFT OFF PROCESS FOR CONDUCTOR FOIL LAYER

(71) Applicant: NTHDEGREE TECHNOLOGIES WORLDWIDE INC., TEMPE, AZ (US)

(72) Inventors: Bradley Steven Oraw, Chandler, AZ (US); Bemly Sujeewa Randeniya, Chandler, AZ (US); Eric William Kahrs, Phoenix, AZ (US)

(73) Assignee: NTHDEGREE TECHNOLOGIES WORLDWIDE INC., TEMPE, AZ (US)

(21) Appl. No.: 14/177,632

(22) Filed: Feb. 11, 2014

Related U.S. Application Data
(60) Provisional application No. 61/766,353, filed on Feb. 19, 2013.

(51) Int. Cl. H05K 3/04

(52) U.S. Cl. CPC H05K 3/048
USPC 29/17.3; 156/154; 156/268

(57) ABSTRACT

A flex-circuit or a rigid printed circuit board is formed by depositing an adhesive pattern on a top surface of a substrate. The adhesive pattern corresponds to a copper foil pattern to be formed for interconnecting electronic components. A thin copper foil is then laminated over the substrate to adhere the foil to the adhesive pattern. The foil is then peeled off the substrate such that the foil overlying the adhesive pattern remains, and the foil that is not overlying the adhesive pattern is removed. In one embodiment, the foil is cut or weakened along the edges of the adhesive pattern to minimize tearing of the foil. The foil may be first affixed to a sheet for increased mechanical integrity, prior to the foil being laminated over the substrate, followed by kiss-cutting the foil while on the sheet to avoid tearing of the foil during the lift-off step.

### CROSS-REFERENCE TO RELATED APPLICATIONS

This application is based on US provisional application Ser. No. 61/766,353, filed Feb. 19, 2013, by Bradley Steven Oraw et al., assigned to the present assignee and incorporated herein by reference.

### FIELD OF THE INVENTION

This invention relates to forming a patterned conductive foil layer on a substrate, such as for forming a circuit board, and, in particular, to forming such a layer using a lift-off process.

### BACKGROUND

Typically, electronic components mounted on a substrate are electrically interconnected together by a patterned copper layer on the substrate. Such circuit “boards” may be rigid or flexible (a flex-circuit). Such circuit boards are commonly formed by laminating a copper foil on a dielectric board, masking the copper, then etching away the exposed copper using a wet etch. This is called a subtractive process. The sheet resistance of such etched copper foil is about 0.5 mOhm/sq. Such processes require etchant materials that must be handled carefully and disposed of properly.

Alternatively, a patterned copper layer may be formed by electroplating, sputtering, evaporation, or other techniques. These methods are complex and time-consuming, and some require vacuum processing. Further, some of these methods do not allow their use in a high-speed manufacturing process.

It is also known to print a silver ink containing silver particles, then sintering the silver particles. Since the resulting silver layer is very thin, using practical methods, a common sheet resistance of such a sintered silver layer is about 50 mOhms/sq. However, higher performance applications require a sheet resistance of 5 mOhms/sq. or less.

What is needed is an inexpensive process for forming a patterned conductor layer on a substrate that requires no etching material, requires no vacuum processing, can be performed at a high speed, and produces a patterned conductor layer having a sheet resistance of 5 mOhms/sq. or less.

### SUMMARY

In one embodiment, a copper foil is provided having a thickness of about 3-5 microns. With such a thickness, the copper foil has a sheet resistance of 5 mOhms/sq. or less and can be easily torn. The foil may have approximately the same dimensions as the substrate to be metalized.

A substrate, such as a flexible or rigid dielectric material of any size, has formed on it a patterned adhesive layer. The adhesive layer may be screen printed or printed using a roller. The copper foil is then laminated over the substrate, such as under heat and pressure to cure the adhesive.

The copper foil is then lifted (peeled) off the substrate, starting at one end. The thin copper foil remains over the adhesive but tears at the edges of the adhesive, and the excess foil is removed and recycled.

If the integrity of the copper foil is such that the tears would not be well-defined, a resilient roller is passed over the substrate under pressure, which pushes the copper foil against the edges of the hardened adhesive pattern to weaken or sever the copper foil. In another embodiment, the roller is abrasive to grind away the copper foil along the edges of the adhesive pattern. The thickness of the adhesive is selected to provide the required height of the edges to achieve the necessary severing of the foil. Instead of a roller, a resilient pad may be used.

In another embodiment, a raised dielectric relief layer may be printed surrounding the patterned adhesive layer. The pattern for the relief layer is thus opposite to the pattern for the adhesive layer. The relief layer is slightly thicker than the adhesive layer. The relief layer may optionally be adhesive. The copper foil is then laminated over the adhesive layer and relief layer. An abrasion tool, such as an abrasive roller or abrasive flat surface, is then brought against the top surface of the structure to abrade the copper foil over the relief layer. The abrasion stops before the foil over the adhesive is abraded. In another embodiment, the relief layer may be printed to just form a thin wall around the patterned adhesive layer.

In another embodiment, the copper foil is first laminated on a thin liner sheet that is less adhesive than the patterned adhesive on the substrate. The liner sheet provides mechanical integrity. The liner sheet with the foil is then laminated over the substrate (having the patterned adhesive layer). The liner sheet is then peeled off, taking the copper foil with it that did not adhere to the patterned adhesive layer. Such a technique is useful if the copper foil by itself would not properly peel off the substrate.

In another embodiment, after the copper foil is laminated to the liner sheet, the copper foil is subjected to a kiss-cut method, wherein a rotary die cuts through the copper foil but does not completely cut through the liner sheet. The cutting is the same pattern as the adhesive pattern on the substrate. After the liner sheet and copper foil are laminated to the substrate and the adhesive layer cured, the liner sheet is peeled from the substrate, and the lifted-off copper foil has the pattern of the kiss-cut. Therefore, there is no tearing in this embodiment.

In another embodiment, the copper foil is laminated over the substrate with the adhesive pattern, and a kiss-cut is performed on the copper foil to cut the foil along the edges of the adhesive layer. The copper foil is then peeled off, leaving the foil that adhered to the adhesive layer.

The processes may be performed using a sheet-based process or a roll-to-roll conveyor type process under atmospheric conditions. Any heating steps may be rapidly performed during the lamination step. If the substrates are flexible, the substrate material and foil are supplied on rolls. The adhesive printing, lamination, curing, kiss-cut, and lift-off may be performed as the materials are moving along a conveyor system. The processed substrates may then be taken up by another roll and later processed for soldering the leads of electronic components to the copper foil. The substrates are eventually cut from the roll for singulation. Such a substrate is known as a flex-circuit.

Variations of the above embodiments are contemplated.

### BRIEF DESCRIPTION OF THE DRAWINGS

FIGS. 1A-1D illustrate laminating a metal foil, such as a copper foil, over a substrate having a patterned adhesive layer, then peeling off the foil, leaving only the foil that adhered to the adhesive layer.

FIGS. 2A-2C illustrate supplying a pressure to and/or abrading the foil, after laminating to the substrate, to sever the foil along the edges of the adhesive layer.

FIGS. 3A-3F illustrate forming a raised relief around the patterned adhesive layer and abrading the foil over the relief layer, leaving only the foil attached to the adhesive layer.

FIGS. 4A-4C illustrate using an adhesive liner sheet to provide mechanical integrity when peeling the foil from the substrate.

FIGS. 5A-5D illustrate kiss-cutting the foil after laminating to the substrate to sever the foil around the edges of the adhesive layer.

FIGS. 6A-6D illustrate kiss-cutting the foil after laminating the foil to the liner sheet, then laminating the foil and liner sheet to the substrate having a patterned adhesive layer, whereby the foil separates along the kiss-cut when the foil and liner sheet are peeled off the substrate.

FIG. 7 illustrates a roll-to-roll process to provide a patterned copper foil on a substrate, where a kiss-cut is performed on the foil when it is laminated to a liner sheet.

FIG. 8 illustrates a roll-to-roll process to provide a patterned copper foil on a substrate, where a kiss-cut is performed on the foil after is it is laminated to the substrate.

Elements that are similar or identical in the various figures are labeled with the same numeral.

### DETAILED DESCRIPTION

Various processes are described for laminating a thin metal foil, such as a 3-5 microns thick copper foil, onto a substrate for forming a pattern of the foil of any complexity. The pattern will be typically used for electrically interconnecting electrical components later mounted on the substrate and soldered to the foil. The substrate having the patterned copper foil may be used instead of any prior art flex-circuit or other type of PCB. To illustrate the invention, only a simple pattern of three rectangles is formed; however, any pattern may be formed. The copper foil may create a pattern having conductors with widths down to about 0.5 mm and pitches down to about 0.5 mm.

The thickness of 3-5 microns for the copper foil was selected for its satisfactory sheet resistance of 5 mOhms/sq., or less, and its ability to tear easily. In some embodiments, tearing is not used, and a thicker foil may be used.

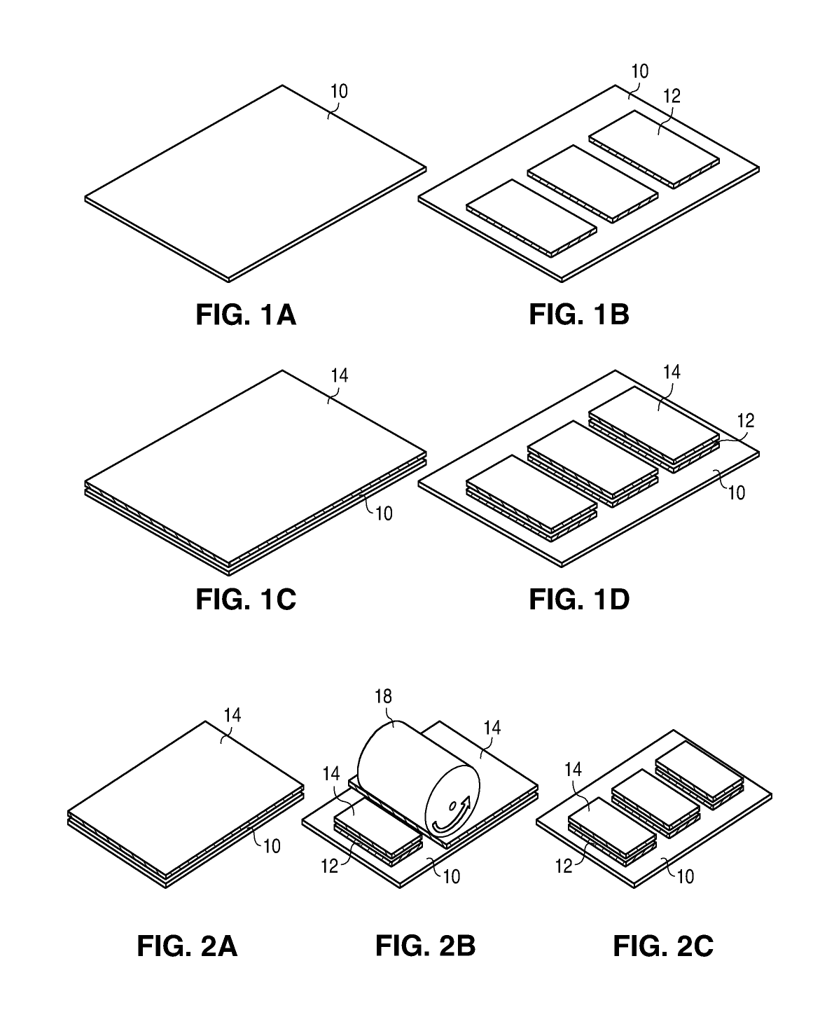

FIGS. 1A-1D illustrate a process in accordance with one embodiment of the invention.

In FIG. 1A, a substrate 10 is provided. The substrate 10 may be a portion of a flexible dielectric material, such as a polymer conventionally used for flexible circuits. One popular flexible film is the Kapton® polyimide film by Dupont. Such material is commercially available. The substrate 10 may be a section of a roll of the material during a roll-to-roll fabrication process, or the substrate 10 may be a flat sheet that is processed individually. The substrate 10 may also be a rigid board conventionally used for printed circuit boards (PCBs).

In FIG. 1B, an adhesive 12 is printed on the substrate 10, where the pattern of the adhesive matches the desired pattern of the copper foil. In the example, three rectangles of the adhesive 12 are printed. The adhesive 12 may be applied by screen printing (a mesh having a masking pattern on it), or a patterned roller, or any other suitable process. The thickness of the adhesive 12 may be, for example, less than 0.1 mm to limit spreading during a subsequent lamination step. Suitable adhesives are inexpensive. There are many types of suitable adhesives that are already used in printed circuit board applications that withstand the expected solder temperatures. Such adhesives are typically used to laminate copper foil to a substrate for subsequent masking and wet etching of the foil, as previously described. Such commercially available adhesives include heat-curable (thermosetting) acrylics, silicones, and epoxies.

In FIG. 1C, the copper foil 14 is laminated over the substrate 10 using heat and pressure. For example, a heated roller may press the foil 14 against the substrate 10 surface and patterned adhesive 12 to concurrently heat-cure the adhesive 12 to form a very strong bond.

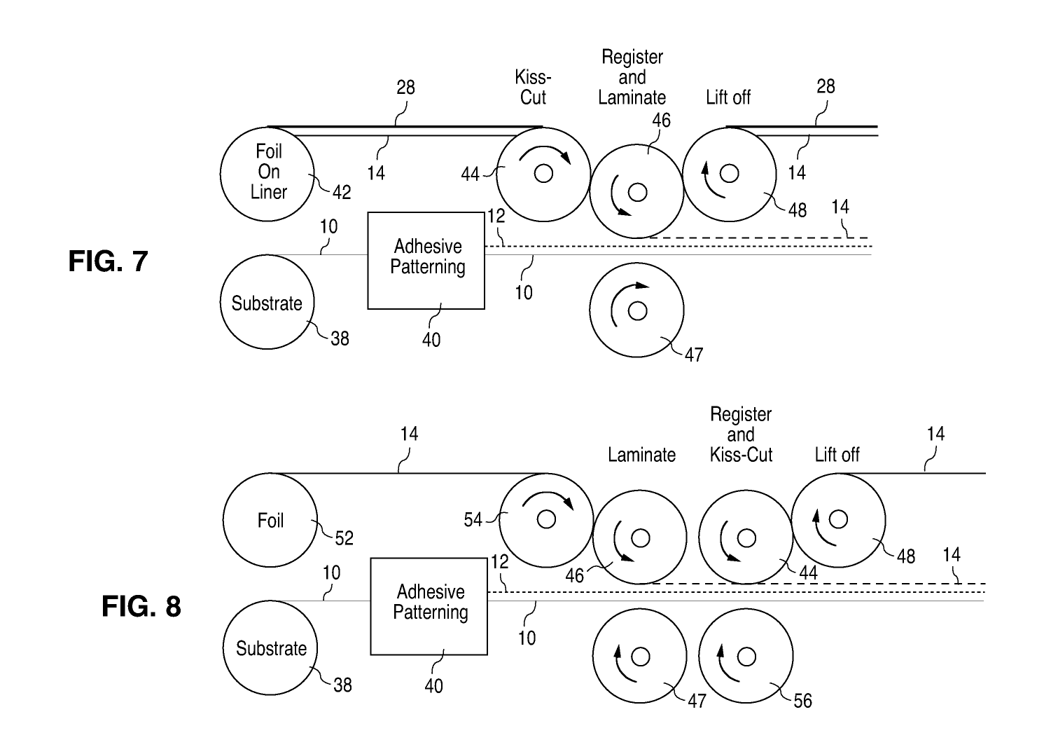

In FIG. 1D, the copper foil 14 has been peeled off the non-adhesive portions of the substrate 10, leaving the foil 14 only over the adhesive 12. The thin copper foil 14 tears easily from the portion of the foil that adheres to the adhesive 12. In one embodiment of a roll-to-roll process, the copper foil 14 is provided on a continuous roll and, after the lamination, the foil is lifted off by a rotating roller above the moving substrate. Another roller rolls up the excess foil for recycling. Such a roll-to-roll process is described later with respect to FIGS. 7 and 8.

Thus, a completed flex-circuit is formed. If holes are needed in the flex-circuit, an additional processing stage may stamp or laser drill holes in the flex circuit. The processed substrates 10 may be later cut from the substrate take-up roll for singulation.

If precise tearing of the copper foil 14 is problematic, any of the following processes may be used. Precise tearing may be a problem if the foil pattern includes very thin conductors with small pitches.

FIG. 2A is identical to FIG. 1C and shows the copper foil 14 laminated to the substrate 10 having the patterned adhesive 12 layer. In FIG. 2B, a roller 18, formed of a resilient material such as a polymer, is pressed against the copper foil 14 while lifting it up. The roller 18 may be coated with a weak tacky adhesive or uses suction. The pressing of the roller 18 thins or cuts the foil 14 along the hard edges of the cured adhesive 12, so that there is minimal force when tearing the excess foil 14 from the substrate 10. The roller 18 may additionally have an abrading surface that cuts or thins the foil 14 along the edges of the adhesive 12 while pressing on it. The lifted-off copper foil 14 is then removed from the roller 18 and rolled up by a foil take-up roller for recycling. The resulting metalized substrate 10 is shown in FIG. 2C, which is identical to FIG. 1D.

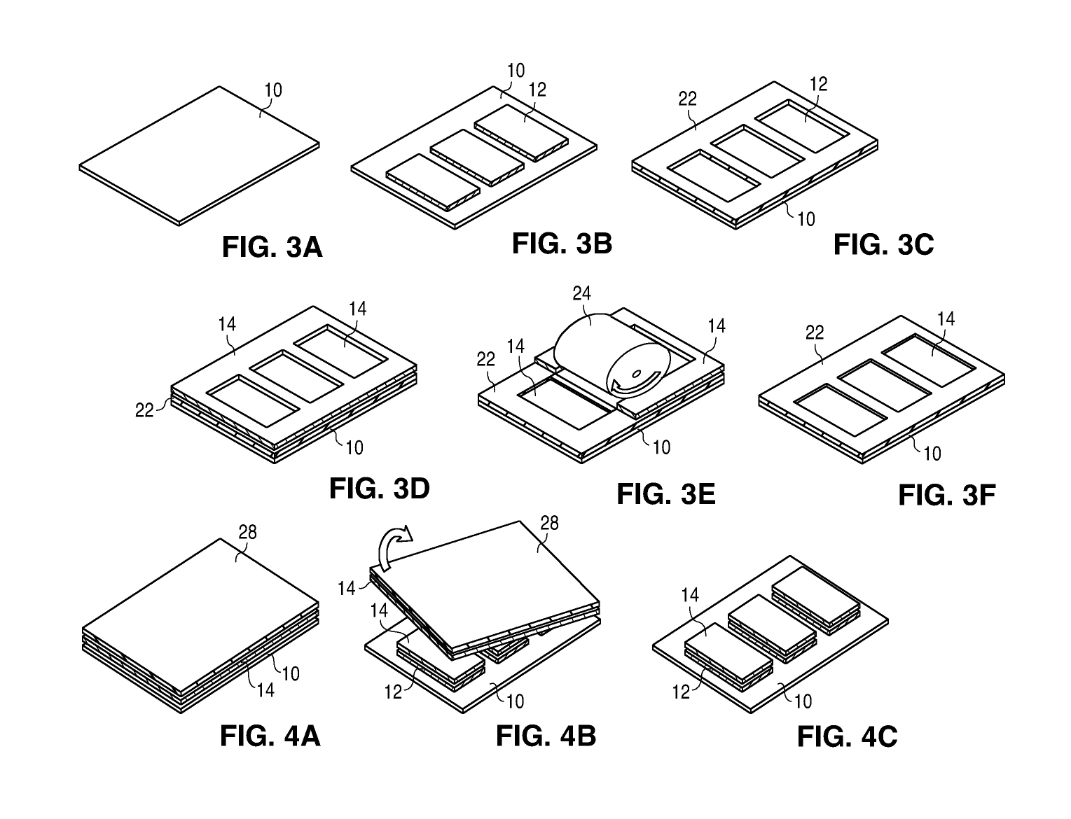

FIGS. 3A-3F illustrate a process for even less tearing stress on the foil 14. FIGS. 3A and 3B are identical to FIGS. 1A and 1B and illustrate the substrate 10 with a patterned adhesive 12 layer. In FIG. 3C, a polymer raised relief layer 22 is formed along the edges of the adhesive 12. This relief layer 22 may be formed using screen printing or a roller with a pattern opposite to the adhesive 12 pattern. Alternatively, to save on material, the relief layer may just form narrow walls around the adhesive 12 edges. The relief layer 22 is only slightly thicker than the adhesive 12 layer to allow the foil 14 to be laminated to the adhesive 12, such as with the use of a resilient laminating roller.

In FIG. 3D, the copper foil 14 is laminated over the substrate 10 to adhere the foil 14 to the adhesive 12.

In FIG. 3E, an abrading roller 24, such as a vibrating roller or a rapidly rotating roller, presses the foil 14 against the raised relief layer 22 without contacting the foil 14 adhered to the adhesive 12. A flat abrading tool may be used instead of the roller 24. The abrasion continues until the foil 14 is removed from over the relief layer 22. If the relief layer 22 is formed in all areas except the adhesive areas, there is then no need for a separate lift off step of any excess foil 14, since the abrading step serves as the lift off step. The abraded foil 14 (as small loose particles) may be removed with suction. If the relief layer 22 is formed as a narrow wall around the adhesive areas, the foil over the wall will be abraded away, and the remaining foil not adhered to the adhesive 12 will be lifted off.

FIG. 3F illustrates the resulting flex-circuit, where the foil 14 is located in the spaces in the relief layer 22.

FIGS. 4A-4C illustrate an embodiment where the copper foil 14 is also laminated to a more mechanically rugged liner sheet 28. The liner sheet 28 may be a thin polymer film that does not tear easily. The foil 14 is laminated to the sheet 28 using a weak adhesive, such as an adhesive that is not completely cured (e.g., hardened). FIG. 4A illustrates the sheet/foil being laminated to the substrate 10, where the substrate 10 has the strong patterned adhesive 12. The adhesive 12 is cured to form a strong bond to the foil 14.

In FIG. 4B, the sheet/foil is lifted (peeled) off the substrate 10. The foil 14 is sufficiently affixed to the sheet 28 to give the foil 14 mechanical integrity so that the foil 14 cannot randomly tear during lift-off. The foil 14 that contacts the adhesive 12 remains bonded to the adhesive 12, and the non-bonded foil 14 remains affixed to the sheet. The tearing of the foil 14 is precisely along the edges of the adhesive 12. The remaining foil 14 on the sheet 28 may later be removed for recycling.

FIG. 4C illustrates the resulting structure, which is identical to FIG. 1D.

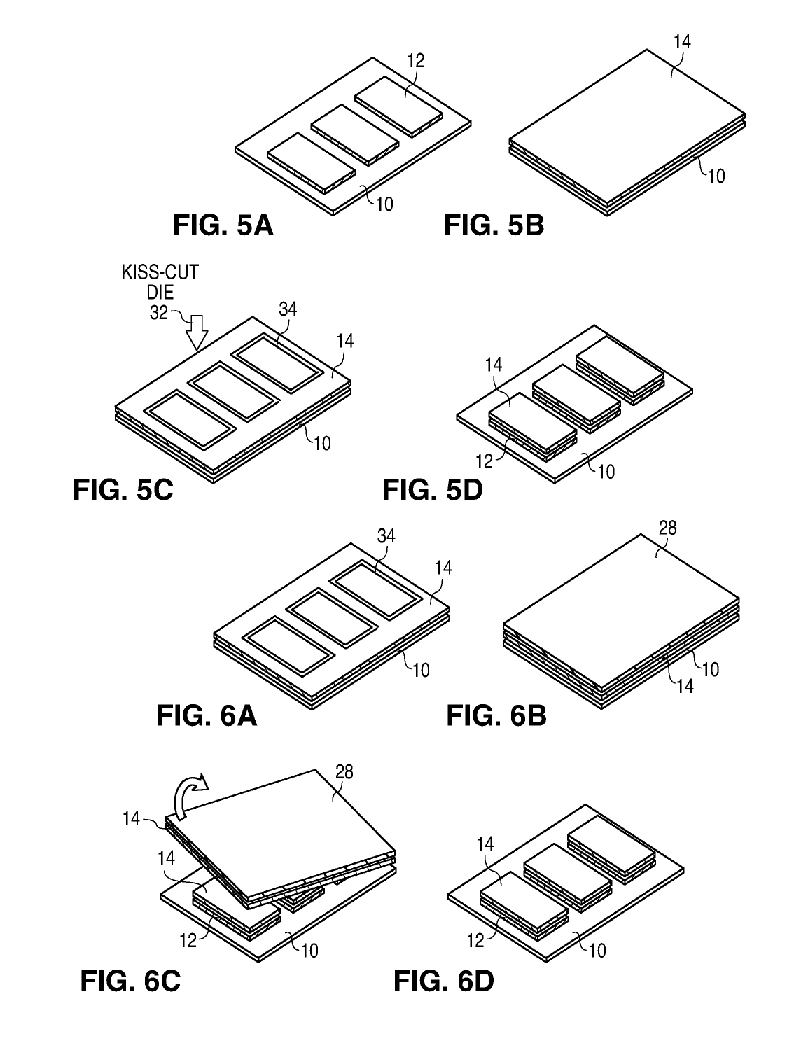

FIGS. 5A-5D illustrate a process where the foil 14 is kiss-cut to cut the foil 14 along the edges of the adhesive 12. FIGS. 5A and 5B are identical to FIGS. 1B and 1C, where the foil 14 is laminated over the substrate 10 and affixed to the adhesive 12.

In FIG. 5C, a rotary die, used as a kiss-cut die 32, has a blade pattern that corresponds to the edges of the adhesive 12. The die 32 is then pressed against the foil 14 to cut the foil 14 but not substantially cut into the substrate 10. The pattern 34 of the cut is shown in FIG. 5C. By using a rotary die 32, the kiss-cut may be performed in a roll-to-roll conveyor process.

In FIG. 5D, the copper foil 14 is lifted off, such as by a take-up roller, leaving only the foil 14 that adheres to the adhesive 12. FIG. 5D is identical to FIG. 1D.

FIGS. 6A-6D illustrate a process where the kiss-cut is performed on the foil 14 after it is affixed to the liner sheet 28 using a strong or weak adhesive. FIG. 6A illustrates the foil 14 side of the sheet/foil lamination. The kiss-cut die 32 of FIG. 5C may be used to cut the pattern 34 into the foil 14 which only partially cuts into the sheet 28. The pattern 34 corresponds to the adhesive 12 pattern on the substrate 10.

In FIG. 6B, the sheet/foil is laminated on the substrate 10 having the adhesive 12 pattern.

In FIG. 6C, the sheet/foil is lifted off the substrate 10, leaving behind the foil 14 affixed to the adhesive 12 without any tearing.

FIG. 6D illustrates the resulting structure, which is identical to FIG. 1D.

The final substrate with the metal foil pattern is then used as a flex-circuit or rigid PCB, where the substrate and foil are populated with electronic components, such as light emitting diodes, capacitors, resistors, ICs, transistors, diodes, etc., and the leads of the components are soldered or otherwise welded to the foil to electrically interconnect the components. For example, resistor leads may be soldered between the rightmost two foil regions in FIG. 1D (or any of the other foil regions in the other figures), and capacitor leads may be soldered to the same two foil regions to connect the resistor and capacitor in parallel.

The inventive flex-circuit or rigid PCB is used exactly as a conventional flex-circuit or rigid PCB would be used. The difference in structure between the inventive circuit board and the conventional structures will at least be the adhesive pattern below the foil that defines the foil pattern.

FIG. 7 illustrates one possible roll-to-roll process for carrying out the process of FIGS. 6A-6D. A roll 38 of the flexible substrate 10 material is provided. The substrate 10 material is continuously or periodically unrolled during processing, and the completed substrate is taken up by a take-up roll (not shown). The completed substrate may then be singulated for use as a flex-circuit or further processed by soldering electronic components to it, then singulated. The foil pattern is determined by the particular application of the flex-circuit.

Each flex-circuit may be processed for only a few cents, and the fabrication may take only a few seconds per substrate.

As the substrate 10 material is unrolled, the adhesive 12 may be applied by an adhesive patterning tool 40. The tool 40 may comprise a roller or a stamp that prints the adhesive 12 on the substrate 10 with the desired pattern. At the same time, the previously laminated sheet 28/foil 14, described with respect to FIG. 6A, is unrolled from a roll 42. The foil 14 is then kiss-cut by a rotary die 44, as described with respect to FIG. 6A, to create a cut pattern that matches the adhesive 12 pattern.

The foil 14 side is then laminated to the substrate 10 by the register/laminate roller 46, which also heats the adhesive 12 to harden it and strongly affix it to the foil 14. A pressure roller 47 applies pressure, and optionally heat, during lamination.

The sheet 28 and foil 14 are then lifted off the substrate 10 by a lift-off roller 48, where the foil 14 that remains on the sheet 28 is that which did not adhere to the adhesive 12.

The sheet/foil is then taken up by a take-up roll (not shown), and the resulting metalized substrate is taken up by a separate take-up roll (not shown). Any holes that are needed to be formed in the flex-circuit may be formed by an additional punching or laser drilling stage.

FIG. 8 illustrates one possible roll-to-roll process for carrying out the process of FIGS. 5A-5D. The roll 38 of the flexible substrate 10 material and the adhesive patterning tool 40 may be the same as described with respect to FIG. 7.

The copper foil 14 is unrolled from a roll 52 via a roller 54 and then laminated onto the substrate 10 by the heated roller 46. A rotary kiss-cut die 44 then cuts the foil 14, as described with respect to FIG. 5C, along the edges of the adhesive 12 pattern. The rollers 47 and 56 provide pressure.

The foil 14 is then lifted off the substrate 10 by the lift-off roller 48, where the foil 14 that is lifted is that which did not adhere to the adhesive 12. The foil 14 is then taken up by a take-up roll (not shown), and the resulting metalized substrate is taken up by a separate take-up roll (not shown). Any holes that are needed to be formed in the flex-circuit may be formed by an additional punching or laser drilling stage.

Conductive foils other than metal foils may be used.

For a rigid substrate 10, a sheet-type fabrication process may be used, where a stack of substrates 10 is processed. Each rigid substrate 10 may be processed using the conveyor process of FIG. 7 or 8, except the substrates 10 are not provided on a roll. The resulting metalized substrates may resemble conventional PCBs.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A substrate metalization process comprising:
providing a substrate having a top surface;
depositing an adhesive pattern on the top surface, the adhesive pattern corresponding to a metal foil pattern to be formed for interconnecting electronic components there to;
laminating a metal foil over the substrate, including directly on the adhesive pattern to adhere the foil to the adhesive pattern; and
lifting off the metal foil such that the foil overlying and adhering to the adhesive pattern remains after lifting off, and the foil that is not overlying the adhesive pattern and did not adhere to the adhesive pattern is removed, such that a resulting foil pattern substantially corresponds to the adhesive pattern.

2. The process of claim 1 wherein the step of lifting off comprises tearing the foil around edges of the adhesive pattern as the foil is lifted off the substrate.

3. The process of claim 1 further comprising providing a pressure at least on edges of the adhesive pattern, prior to the step of lifting off, to weaken or sever the foil around the edges of the adhesive pattern.

4. The process of claim 3 further comprising abrading a surface of the foil at least over the edges of the adhesive pattern, prior to the step of lifting off, to weaken or sever the foil around the edges of the adhesive pattern.

5. The process of claim 3 wherein the step of providing a pressure comprises moving a roller over the foil.

6. The process of claim 1 further comprising:
prior to laminating the metal foil, forming a raised relief pattern at least around edges of the adhesive pattern, wherein a top surface of the relief pattern is above a top surface of the adhesive pattern;
wherein the step of laminating comprises laminating the metal foil over the adhesive pattern and the top surface of the relief pattern; and
abrading the foil on the top surface of the relief pattern to lift off the foil at least around edges of the adhesive pattern but not abrade the foil over the adhesive pattern.

7. The process of claim 6 wherein the relief pattern forms a wall around the edges of the adhesive pattern, the wall having a top surface, wherein abrading the foil removes the foil from the top surface of the wall, and wherein the remaining foil not adhered to the adhesive pattern is then lifted off.

8. The process of claim 6 wherein the relief pattern is a pattern substantially opposite to the adhesive pattern, wherein abrading the foil removes the foil from over the relief pattern to lift off the foil that has not adhered to the adhesive pattern.

9. The process of claim 1 further comprising kiss-cutting the foil, after the step of laminating the foil over the substrate, to cut or weaken the foil along edges of the adhesive pattern prior to the step of lifting off the metal foil, wherein the kiss-cutting does not cut completely through the substrate.

10. The process of claim 1 further comprising:
prior to laminating the metal foil over the substrate, affixing the metal foil to a sheet via a first adhesive, the first adhesive providing an adhesion of the foil to the sheet that is weaker than an adhesion of the foil to the adhesive pattern;
wherein the step of laminating the metal foil to the substrate comprises laminating the foil and sheet to the substrate so that the foil directly contacts the adhesive pattern and adheres to the adhesive pattern; and
wherein the step of lifting off the metal foil comprises lifting off both the sheet and the foil so that the foil overlying the adhesive pattern remains affixed to the adhesive pattern, and the foil not overlying the adhesive pattern is lifted off.

11. The process of claim 10 further comprising kiss-cutting the foil while the foil is affixed to the sheet to cut or weaken the foil in a pattern corresponding to the adhesive pattern, where the kiss-cutting does not cut completely though the sheet.

12. The process of claim 1 wherein the process is a roll-to-roll process, wherein the substrate is a flexible material provided on a first roll, the metal foil is provided on a second roll, and the steps of depositing, laminating, and lifting off are performed at stages in a process line as the substrate and the foil are unrolled.

13. The process of claim 1 further comprising electrically connecting electronic components to the foil, after the step of lifting off, to interconnect the components.

14. The process of claim 1 wherein the substrate having the foil pattern is a flexible circuit.

15. The process of claim 1 wherein the substrate having the foil pattern is a rigid printed circuit board.

16. The process of claim 1 wherein the metal foil comprises copper.

17. The process of claim 1 wherein the substrate comprises a dielectric material.

18. The process of claim 1 wherein the metal foil has a thickness of 5 microns or less.
